(19) United States
(12) Patent Application Publication
(10) Pub. No.: US 2025/0324621 A1
(43) Pub. Date: Oct. 16, 2025

(54) CAPACITOR STRUCTURE AND MANUFACTURING METHOD THEREOF

(71) Applicant: UNITED MICROELECTRONICS CORP., Hsin-Chu City (TW)

(72) Inventors: Chin-Hung Chen, Tainan City (TW); Ssu-I Fu, Kaohsiung City (TW); Po-Kuang Hsieh, Kaohsiung City (TW); Chun-Ya Chiu, Tainan City (TW); Yu-Hsiang Lin, New Taipei City (TW)

(73) Assignee: UNITED MICROELECTRONICS CORP., Hsin-Chu City (TW)

(21) Appl. No.: 18/675,182

(22) Filed: May 28, 2024

(30) Foreign Application Priority Data
Apr. 10, 2024 (TW) 113113266

(51) Int. Cl. H10D 1/00; H10D 1/68

(52) U.S. Cl. CPC H10D 1/042; H10D 1/716

(57) ABSTRACT

A capacitor structure includes a semiconductor substrate, a first electrode disposed above the semiconductor substrate in a vertical direction, a capacitor dielectric layer disposed on the first electrode, a second electrode disposed on the capacitor dielectric layer, a patterned mask layer disposed on the second electrode, and a cover layer disposed conformally on the patterned mask layer, the capacitor dielectric layer, and the first electrode. The capacitor dielectric layer includes a first extending portion. The first extending portion is not covered by the second electrode in the vertical direction. The cover layer includes a sidewall disposed above the first extending portion of the capacitor dielectric layer in the vertical direction. A distance between the sidewall of the cover layer and a sidewall of the patterned mask layer in a horizontal direction is greater than a thickness of the cover layer disposed above the patterned mask layer in the vertical direction.

### BACKGROUND OF THE INVENTION

### 1. Field of the Invention

The present invention relates to a capacitor structure and a manufacturing method thereof, and more particularly, to a capacitor structure including a capacitor dielectric layer and a manufacturing method thereof.

### 2. Description of the Prior Art

In modern society, the micro-processor systems composed of integrated circuits (ICs) are applied popularly in our living. Many electrical products, such as personal computers, mobile phones, and home appliances, include ICs. With the development of technology and the increasingly imaginative applications of electrical products, the design of ICs tends to be smaller, more delicate and more diversified.

In the recent electrical products, IC devices, such as metal oxide semiconductor (MOS) transistors, capacitors, or resistors, are produced from silicon based substrates that are fabricated by semiconductor manufacturing processes. A complicated IC system may be composed of the IC devices electrically connected with one another. Generally, a capacitor structure may be composed of a top electrode, a dielectric layer, and a bottom electrode.

Additionally, to accommodate the exceedingly demanding power integrity (PI) requirements for the advanced artificial intelligence (AI) and high performance computing (HPC) components, high dielectric constant based deep trench capacitors (DTC) have been integrated in the silicon interposer including through silicon via (TSV) and interconnection structures for being applied in advanced packaging technology (such as CoWoS package technology). Capacitor structures generally require multiple layers of metal electrodes and high dielectric constant film layers. For forming via structures, different electrodes are partially disposed misaligned with one another, and the step height may be formed accordingly and influence the coverage of the protection layer covering the capacitor structure.

### SUMMARY OF THE INVENTION

A capacitor structure and a manufacturing method thereof are provided in the present invention. A cover layer is formed conformally on a patterned mask layer, a capacitor dielectric layer, and a first electrode, and a distance between a sidewall of the cover layer and a sidewall of the patterned mask layer is relatively increased for improving coverage condition of the cover layer and enhancing related manufacturing yield.

According to an embodiment of the present invention, a capacitor structure is provided. The capacitor structure includes a semiconductor substrate, a first electrode, a capacitor dielectric layer, a second electrode, a patterned mask layer, and a cover layer. The first electrode is disposed above the semiconductor substrate in a vertical direction. The capacitor dielectric layer is disposed on the first electrode, and the second electrode is disposed on the capacitor dielectric layer. The capacitor dielectric layer includes a first extending portion, and the first extending portion is not covered by the second electrode in the vertical direction. The patterned mask layer is disposed on the second electrode. The cover layer is disposed conformally on the patterned mask layer, the capacitor dielectric layer, and the first electrode. The cover layer includes a sidewall disposed above the first extending portion of the capacitor dielectric layer in the vertical direction. A distance between the sidewall of the cover layer and a sidewall of the patterned mask layer in a horizontal direction is greater than a thickness of the cover layer disposed above the patterned mask layer in the vertical direction.

According to an embodiment of the present invention, a manufacturing method of a capacitor structure is provided. The manufacturing method includes the following steps. A semiconductor substrate is provided, and a first electrode, a capacitor dielectric layer, a second electrode, and a patterned mask layer are formed on the semiconductor substrate. The first electrode is located above the semiconductor substrate in a vertical direction, the capacitor dielectric layer is located on the first electrode, the second electrode is located on the capacitor dielectric layer, and the patterned mask layer is located on the second electrode. The capacitor dielectric layer includes a first extending portion, and the first extending portion is not covered by the second electrode in the vertical direction. A cover layer is formed conformally on the patterned mask layer, the capacitor dielectric layer, and the first electrode. The cover layer includes a sidewall located above the first extending portion of the capacitor dielectric layer in the vertical direction. A distance between the sidewall of the cover layer and a sidewall of the patterned mask layer in a horizontal direction is greater than a thickness of the cover layer formed above the patterned mask layer in the vertical direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a capacitor structure according to a first embodiment of the present invention.

FIGS. 2-9 are schematic drawings illustrating a manufacturing method of a capacitor structure according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, and FIG. 9 is a schematic drawing in a step subsequent to FIG. 8.

FIG. 10 is a schematic drawing illustrating a capacitor structure according to a second embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

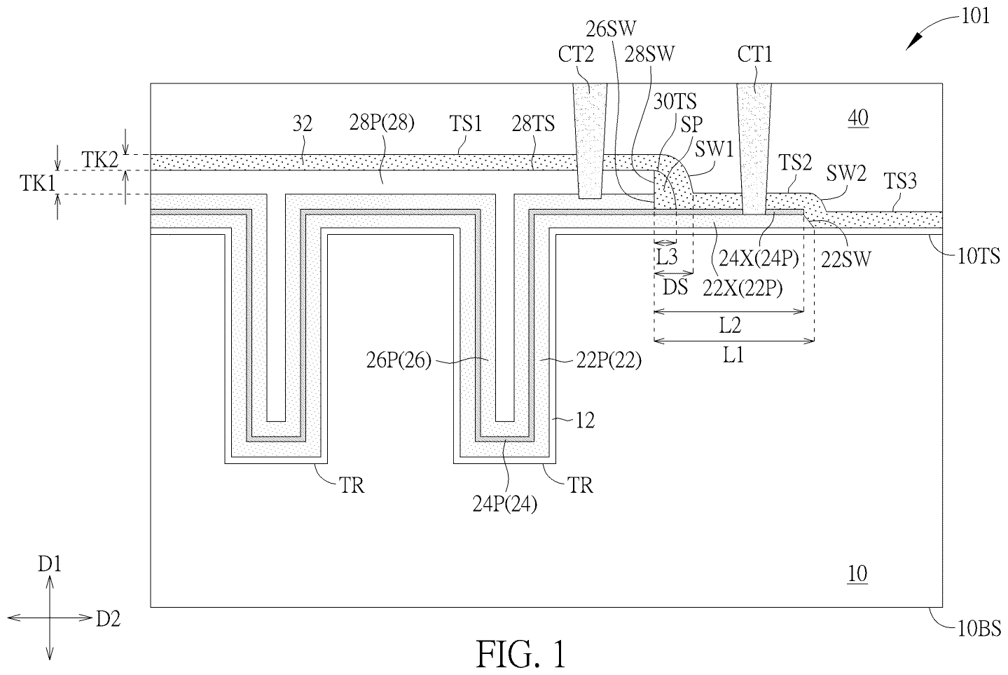

Please refer to FIG. 1. FIG. 1 is a schematic drawing illustrating a capacitor structure 101 according to a first embodiment of the present invention. As shown in FIG. 1, the capacitor structure 101 includes a semiconductor substrate 10, a first electrode 22P, a capacitor dielectric layer 24P, a second electrode 26P, a patterned mask layer 28P, and a cover layer 32. The first electrode 22P is disposed above the semiconductor substrate 10 in a vertical direction D1, the capacitor dielectric layer 24P is disposed on the first electrode 22P, the second electrode 26P is disposed on the capacitor dielectric layer 24P, and the patterned mask layer 28P is disposed on the second electrode 26P. The capacitor dielectric layer 24P includes a first extending portion (such as an extending portion 24X), and the extending portion 24X is not covered by the second electrode 26P in the vertical direction D1. The cover layer 32 is disposed conformally on the patterned mask layer 28P, the capacitor dielectric layer 24P, and the first electrode 22P. The cover layer 32 includes a sidewall SW1 disposed above the extending portion 24X of the capacitor dielectric layer 24P in the vertical direction D1. A distance DS between the sidewall SW1 of the cover layer 32 and a sidewall 28SW of the patterned mask layer 28P in a horizontal direction D2 is greater than a thickness TK2 of the cover layer 32 disposed above the patterned mask layer 28P in the vertical direction D1. The distance between the sidewall SW1 of the cover layer 32 and the sidewall 28SW of the patterned mask layer 28P is increased for reducing the influence of the stress and/or the surface step height of the patterned mask layer 28P, the second electrode 26P, and the capacitor dielectric layer 24P on the portion of the cover layer 32 located adjacent to the sidewall SW1, and the covering performance of the cover layer 32 may be improved accordingly for enhancing related manufacturing yield.

In some embodiments, the semiconductor substrate 10 may include a silicon substrate, such as at least a portion of a silicon interposer for packaging processes, but not limited thereto. In some embodiments, the semiconductor substrate 10 may include a base substrate and a dielectric layer disposed on the base substrate, the base substrate may include a semiconductor material, and semiconductor units (such as transistors, diodes, and so forth, but not limited thereto) may be disposed on the base substrate. In some embodiments, the vertical direction D1 may be regarded as a thickness direction of the semiconductor substrate 10, the semiconductor substrate 10 may have a top surface 10TS and a bottom surface 10BS opposite to the top surface 10TS in the vertical direction D1, and the first electrode 22P, the capacitor dielectric layer 24P, the second electrode 26P, the patterned mask layer 28P, and the cover layer 32 may be at least partially disposed at the side of the top surface 10TS. Horizontal directions substantially orthogonal to the vertical direction D1 (such as the horizontal direction D2) may be substantially parallel with the top surface 10TS and/or the bottom surface 10BS of the semiconductor substrate 10, but not limited thereto. In this description, a distance between the bottom surface 10BS of the semiconductor substrate 10 and a relatively higher location and/or a relatively higher part in the vertical direction D1 may be greater than a distance between the bottom surface 10BS of the semiconductor substrate 10 and a relatively lower location and/or a relatively lower part in the vertical direction D1. The bottom or a lower portion of each component may be closer to the bottom surface 10BS of the semiconductor substrate 10 in the vertical direction D1 than the top or upper portion of this component. Another component disposed above a specific component may be regarded as being relatively far from the bottom surface 10BS of the semiconductor substrate 10 in the vertical direction D1, and another component disposed under a specific component may be regarded as being relatively close to the bottom surface 10BS of the semiconductor substrate 10 in the vertical direction D1, but not limited thereto. It is worth noting that, in this description, a top surface of a specific component may include the topmost surface of this component in the vertical direction D1, and a bottom surface of a specific component may include the bottommost surface of this component in the vertical direction D1, but not limited thereto. Additionally, in this description, the condition that a certain component is disposed between two other components in a specific direction may include but is not limited to a condition that the certain component is sandwiched between the two other components in the specific direction.

In some embodiments, the first electrode 22P and the second electrode 26P may include titanium nitride (TiN) or other suitable metallic electrically conductive materials. The capacitor dielectric layer 24P may include a ZrO₂/Al₂O₃/ZrO₂ (ZAZ) stacked dielectric structure or other suitable high dielectric constant dielectric materials. The first electrode 22P, the capacitor dielectric layer 24P, and the second electrode 26P may constitute a metal-insulator-metal (MIM) capacitor. Additionally, in some embodiments, the capacitor structure 101 may further include at least one trench TR disposed in the semiconductor substrate 10. The first electrode 22P, the capacitor dielectric layer 24P, the second electrode 26P, and the patterned mask layer 28P may be partly disposed in the trench TR and partly disposed outside the trench TR (such as being disposed above the top surface 10TS of the semiconductor substrate 10), and the capacitor structure 101 may include a deep trench capacitor (DTC) structure accordingly. In some embodiments, the capacitor structure 101 may further include a dielectric layer 12 disposed conformally on an inner sidewall and a bottom surface of the trench TR and the top surface 10TS of the semiconductor substrate 10, and the first electrode 22P may be disposed on the dielectric layer 12. The dielectric layer 12 may include an oxide dielectric material or other suitable dielectric materials, and the dielectric layer 12 may be regarded as a dielectric liner layer, but not limited thereto. The patterned mask layer 28P may include an oxide dielectric material or other suitable dielectric materials, and the patterned mask layer 28P may be used to define the second electrode 26P and/or be used as a filling material formed in the trench TR, but not limited thereto.

In some embodiments, the first electrode 22P may include a second extending portion (such as an extending portion 22X), and the extending portion 22X may be located under the extending portion 24X of the capacitor dielectric layer 24P in the vertical direction D1. The extending portion 22X and the extending portion 24X may be regarded as the portion of the first electrode 22P and the portion of the capacitor dielectric layer 24P without being covered by the second electrode 26P and the patterned mask layer 28P in the vertical direction D1, respectively. In other words, when the capacitor structure 101 is viewed in the vertical direction D1, the extending portion 22X and the extending portion 24X do not overlap the second electrode 26P and/or the patterned mask layer 28P. In some embodiments, the capacitor structure 101 may further include a spacer structure SP disposed on the sidewall 28SW of the patterned mask layer 28P and a sidewall 26SW of the second electrode 26P, the spacer structure SP may be located above the extending portion 24X of the capacitor dielectric layer 24P and the extending portion 22X of the first electrode 22P in the vertical direction D1, and the spacer structure SP may be located outside the trench TR. In some embodiments, the sidewall 28SW of the patterned mask layer 28P and the sidewall 26SW of the second electrode 26P may be located above the top surface 10TS of the semiconductor substrate 10 in the vertical direction D1, and the sidewall 28SW and the sidewall 26SW may be substantially aligned with each other in the vertical direction D1 and/or flush with each other, but not limited thereto. A material of the spacer structure SP may include silicon nitride or other suitable insulation materials, and the spacer structure SP may directly contact the sidewall 28SW of the patterned mask layer 28P, the sidewall 26SW of the second electrode 26P, and the extending portion 24X of the capacitor dielectric layer 24P. In some embodiments, a top surface 30TS of the spacer structure SP and a top surface 28TS of the patterned mask layer 28P may be coplanar or the top surface 30TS of the spacer structure SP may be lower than the top surface 28TS of the patterned mask layer 28P and higher than a top surface of the second electrode 26P in the vertical direction D1. In other words, the spacer structure SP may cover the sidewall 26SW of the second electrode 26P completely and cover the sidewall 28SW of the patterned mask layer 28P completely or partially.

In some embodiments, the cover layer 32 may be disposed conformally on and directly contact the top surface 28TS of the patterned mask layer 28P, the spacer structure SP, the extending portion 24X of the capacitor dielectric layer 24P, a sidewall 22SW of the extending portion 22X of the first electrode 22P, and a top surface of the dielectric layer 12. Because of the influence of the step height formed by the material layers described above, the cover layer 32 may have a top surface TS1, the sidewall SW1, a top surface TS2, a sidewall SW2, and a top surface TS3. The top surface TS1 may be regarded as a flat top surface of the cover layer 32 disposed above the patterned mask layer 28P in the vertical direction D1, the top surface TS2 may be regarded as a flat top surface of the cover layer 32 disposed above the extending portion 24X of the capacitor dielectric layer 24P in the vertical direction D1 and directly contacting the extending portion 24X, and the top surface TS3 may be regarded as the a flat top surface of the cover layer 32 disposed above the dielectric layer 12 in the vertical direction D1 and directly contacting the dielectric layer 12. The top portion and the bottom portion of the sidewall SW1 may be directly connected with the top surface TS1 and the top surface TS2, respectively, and the top portion and the bottom portion of the sidewall SW2 may be directly connected with the top surface TS2 and the top surface TS3, respectively. In some embodiments, the top surface TS1 may be higher than the sidewall SW1, the top surface TS2, the sidewall SW2, and the top surface TS3 in the vertical direction D1, and the top surface TS2 may be higher than the sidewall SW2 and the top surface TS3 in the vertical direction D1, but not limited thereto. The sidewall SW1 of the cover layer 32 may be located above the extending portion 24X of the capacitor dielectric layer 24P and the extending portion 22X of the first electrode 22P in the vertical direction D1, and the spacer structure SP may be disposed between the cover layer 32 (such as the sidewall SW1) and the second electrode 26P in the horizontal direction D2 and disposed between the cover layer 32 (such as the sidewall SW1) and the patterned mask layer 28P in the horizontal direction D2 for increasing the distance between the sidewall SW1 and the second electrode 26P in the horizontal direction D2 and/or the distance between the sidewall SW1 and the patterned mask layer 28P in the horizontal direction D2 (such as the distance DS described above). In some embodiments, the distance DS may be regarded as a distance between a bottom of the sidewall SW1 and the sidewall 26SW of the second electrode 26P in the horizontal direction D2 and/or the bottom of the sidewall SW1 and the sidewall 28SW of the patterned mask layer 28P in the horizontal direction D2, and the distance DS may be greater than a length L3 of the spacer structure SP in the horizontal direction D2.

In some embodiments, the sidewall 22SW of the extending portion 22X of the first electrode 22P may be a sloping sidewall, the sidewall 22SW may be not covered by the extending portion 24X of the capacitor dielectric layer 24P in the vertical direction D1, and at least a part of the sidewall SW2 may be disposed corresponding to the sidewall 22SW of the extending portion 22X. The sidewall 22SW of the extending portion 22X is not orthogonal to the top surface of the dielectric layer 12, and the included angle between the sidewall 22SW of the extending portion 22X and the top surface of the dielectric layer 12 is not equal to 90 degrees. In addition, a length L2 of the extending portion 24X of the capacitor dielectric layer 24P in the horizontal direction D2 may be greater than the length L3 of the spacer structure SP in the horizontal direction D2 and the distance DS between the sidewall SW1 of the cover layer 32 and the sidewall 28SW of the patterned mask layer 28P in the horizontal direction D2, and a length L1 of the extending portion 22X of the first electrode 22P in the horizontal direction D2 may be greater than the length L2 of the extending portion 24X of the capacitor dielectric layer 24P in the horizontal direction D2. In some embodiments, the patterned mask layer 28P with a specific thickness is required for some process demands (such as being used to define the second electrode 26P and/or being used as a filling material in the trench TR, but not limited thereto), the step height between the top surface TS1 and the top surface TS2 of the cover layer 32 may be greater than the step height between the top surface TS2 and the top surface TS3 of the cover layer 32 because of the influence of the thickness of the patterned mask layer 28P (such as a thickness TK1 of the patterned mask layer 28P located above the top surface 10TS of the semiconductor substrate 10 in the vertical direction D1). A sidewall of the spacer structure SP away from the patterned mask layer 28P and the second electrode 26P may include a curved sidewall, and the spacer structure SP may be disposed for mitigating the surface height difference between the patterned mask layer 28P and the extending portion 24X of the capacitor dielectric layer 24P and the alleviating the surface undulations generated by the sidewall 28SW and the sidewall 26SW which are substantially vertical. The spacer structure SP may be used to increase the overall thickness of the cover material (the spacer structure SP and the cover layer 32 may be collectively regarded as the cover material) located on the sidewall 28SW and the sidewall 26SW in the horizontal direction D2, the problem of peeling and/or breaking of the cover material due to the stress generated by the MIM capacitor stacked structure may be improved accordingly, and the related manufacturing yield may be enhanced. Additionally, in some embodiments, a material composition of the spacer structure SP may be identical to a material composition of the cover layer 32, and the material composition of the spacer structure SP and the cover layer 32 may be different from that of the patterned mask layer 28P, but not limited thereto. For example, a material of the spacer structure SP and a material of the cover layer 32 may include silicon nitride, and a material of the patterned mask layer 28P may include oxide.

In some embodiments, the capacitor structure 101 may further include a dielectric layer 40, a contact structure CT1, and a contact structure CT2. The dielectric layer 40 may be disposed on the cover layer 32, and the dielectric layer 40 may include an oxide dielectric material or other suitable dielectric materials. The contact structure CT1 may penetrate through the dielectric layer 40, the cover layer 32, and the extending portion 24X of the capacitor dielectric layer 24P located above the extending portion 22X of the first electrode 22P in the vertical direction D1 for contacting and being electrically connected with the extending portion 22X of the first electrode 22P. The contact structure CT2 may penetrate through the dielectric layer 40, the cover layer 32, and the patterned mask layer 28P located above the second electrode 26P in the vertical direction D1 for contacting and being electrically connected with the second electrode 26P. The contact structure CT1 and the contact structure CT2 may include a barrier layer and a low resistance material disposed on the barrier layer, the low resistance material may include a material with relatively low electrical resistivity, such as copper, aluminum, tungsten, and so forth, and the barrier layer may include titanium nitride, tantalum nitride, or other suitable electrically conductive materials, but not limited thereto.

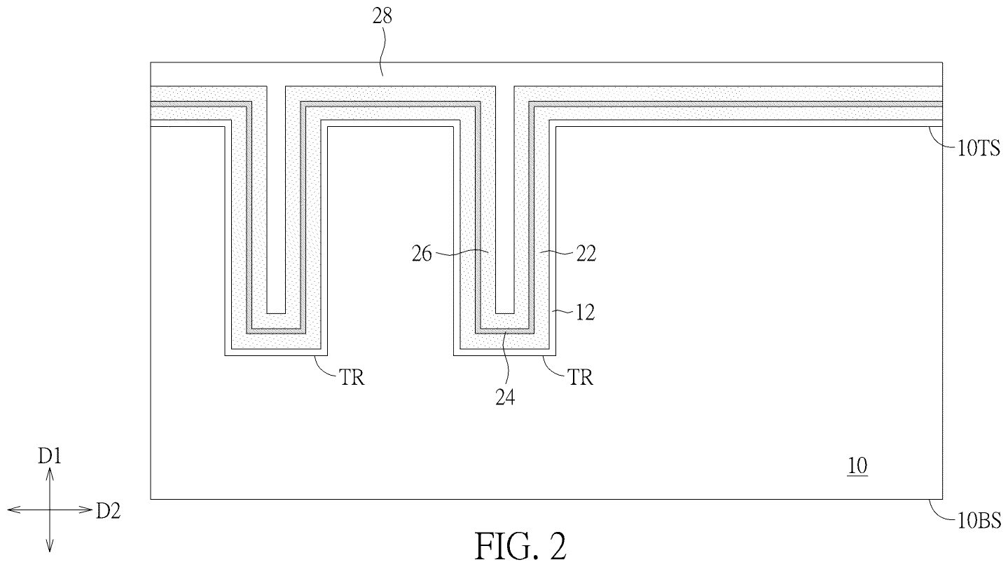

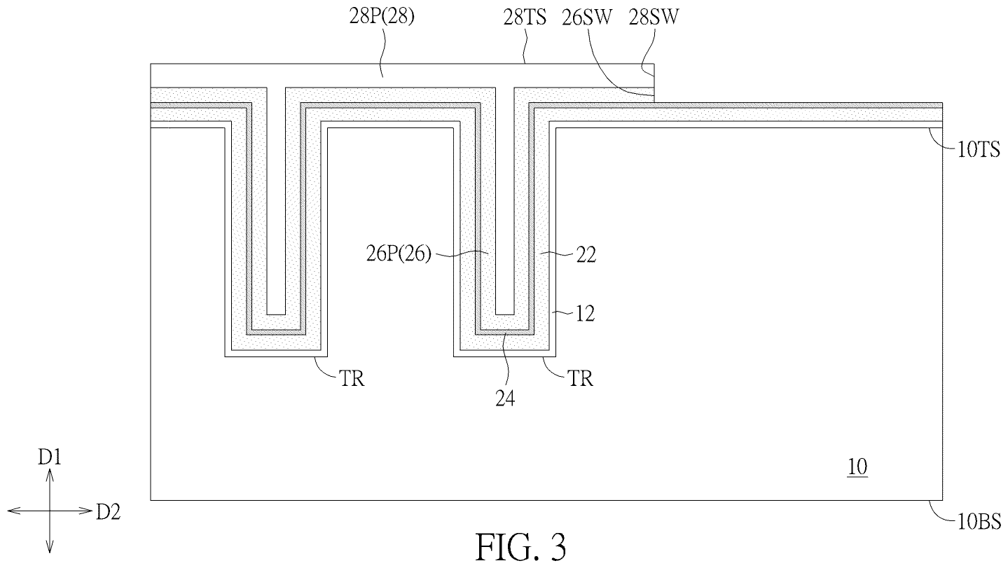

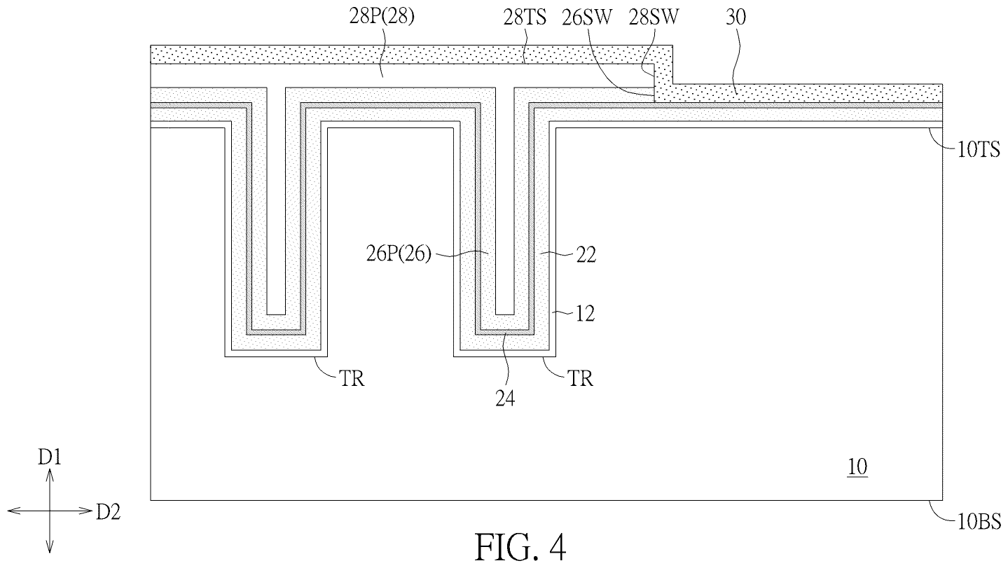

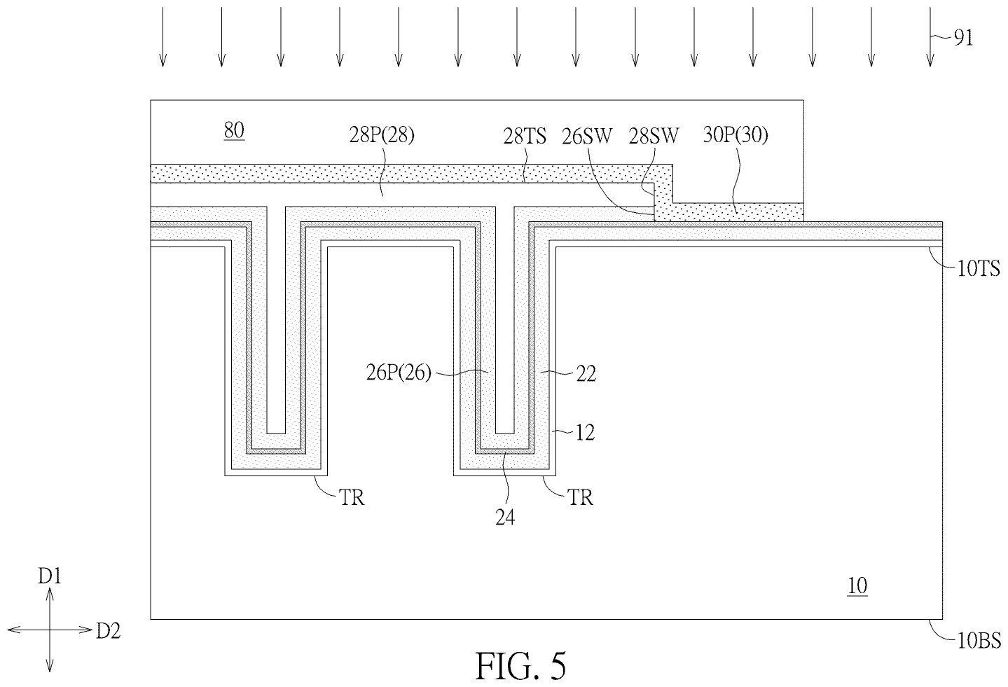

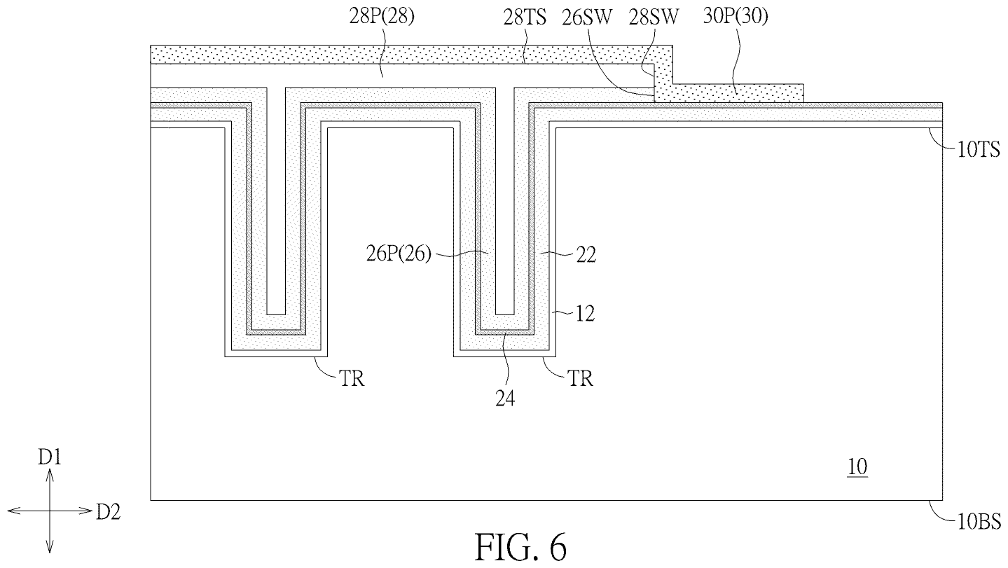

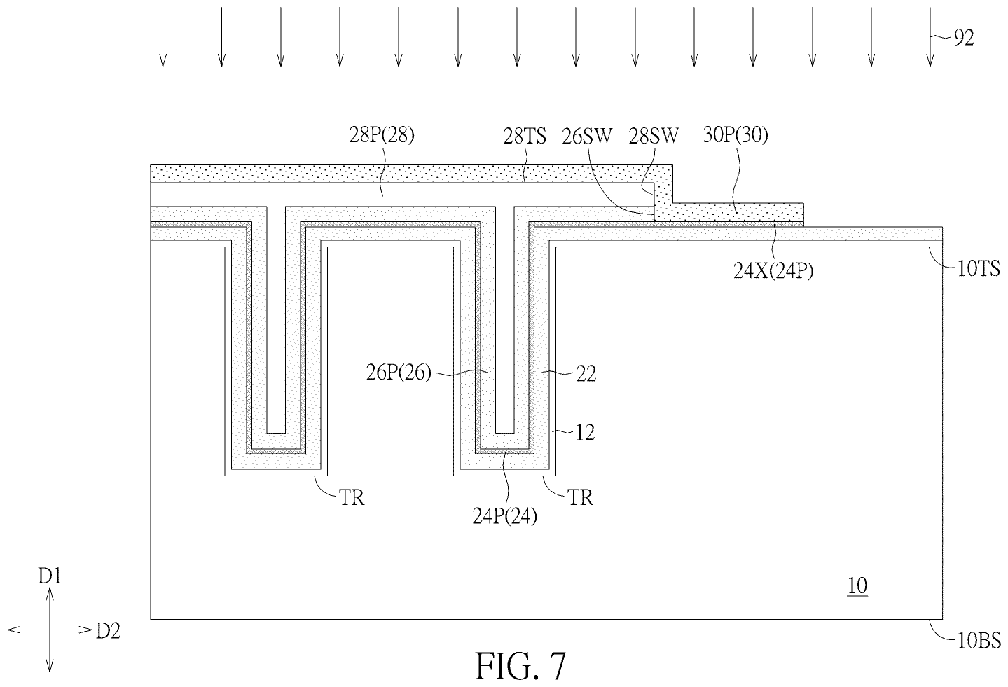

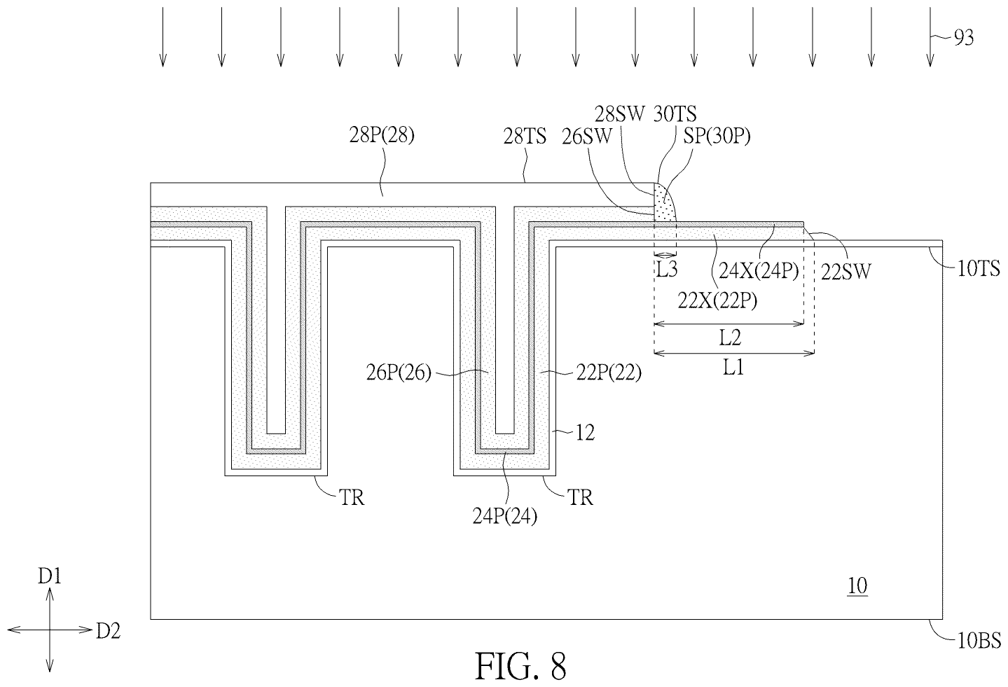

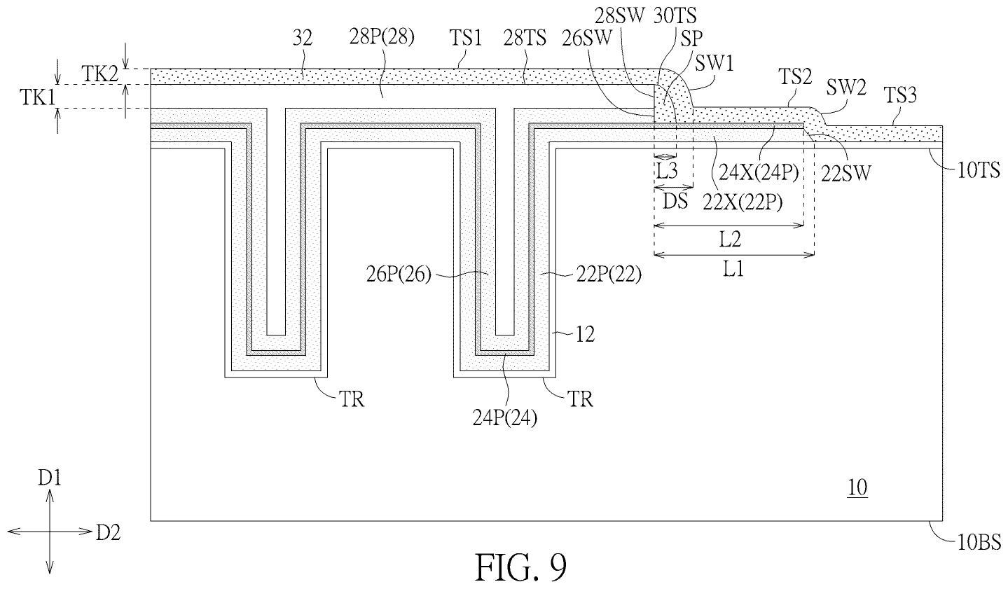

Please refer to FIGS. 1-9. FIGS. 2-9 are schematic drawings illustrating a manufacturing method of a capacitor structure according to an embodiment of the present invention, wherein FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, and FIG. 9 is a schematic drawing in a step subsequent to FIG. 8. In some embodiments, FIG. 1 may be regarded as a schematic drawing in a step subsequent to FIG. 9, but not limited thereto. As shown in FIG. 1, the manufacturing method in this embodiment includes the following steps. The semiconductor substrate 10 is provided, and the first electrode 22P, the capacitor dielectric layer 24P, the second electrode 26P, and the patterned mask layer 28P are formed on the semiconductor substrate 10. The first electrode 22P is located above the semiconductor substrate 10 in the vertical direction D1, the capacitor dielectric layer 24P is located on the first electrode 22P, the second electrode 26P is located on the capacitor dielectric layer 24P, and the patterned mask layer 28P is located on the second electrode 26P. The capacitor dielectric layer 24P includes a first extending portion (such as the extending portion 24X), and the extending portion 24X is not covered by the second electrode 26P in the vertical direction D1. Subsequently, the cover layer 32 is formed conformally on the patterned mask layer 28P, the capacitor dielectric layer 24P, and the first electrode 22P. The cover layer 32 includes the sidewall SW1 located above the extending portion 24X of the capacitor dielectric layer 24P in the vertical direction D1. The distance DS between the sidewall SW1 of the cover layer 32 and the sidewall 28SW of the patterned mask layer 28P in the horizontal direction D2 is greater than the thickness TK2 of the cover layer 32 formed above the patterned mask layer 28P in the vertical direction D1.

Specifically, the manufacturing method in this invention may include but is not limited to the following steps. As shown in FIG. 2, at least a trench TR may be formed in the semiconductor substrate 10, and the dielectric layer 12, an electrode material 22, a capacitor dielectric material 24, an electrode material 26, and a mask material 28 may be sequentially formed on the semiconductor substrate 10 after the trench TR is formed. The dielectric layer 12 may be formed conformally on the top surface 10TS of the semiconductor substrate 10 and the inner sidewall and the bottom surface of the trench TR. The electrode material 22 may be formed conformally on the dielectric layer 12, the capacitor dielectric material 24 may be formed conformally on the electrode material 22, the electrode material 26 may be formed conformally on the capacitor dielectric material 24, and the mask material 28 may be formed on the electrode material 26 and fill the trench TR. The dielectric layer 12, the electrode material 22, the capacitor dielectric material 24, the electrode material 26, and the mask material 28 may be partly formed on the trench TR and partly formed outside the trench TR. Subsequently, as shown in FIG. 2 and FIG. 3, a patterning process may be performed to the mask material 28 and the electrode material 26 for forming the patterned mask layer 28P and the second electrode 26P on the capacitor dielectric material 24. In some embodiments, the mask material 28 and the electrode material 26 may be patterned by the same patterning process (such as a photolithographic and etching process) to become the patterned mask layer 28P and the second electrode 26P, respectively, and the sidewall 28SW of the patterned mask layer 28P and the sidewall 26SW of the second electrode 26P may be aligned with each other in the vertical direction D1 and/or flush with each other accordingly, but not limited thereto. As show in FIG. 3 and FIG. 4, after the patterned mask layer 28P and the second electrode 26P are formed, a spacer material 30 may be formed covering the top surface 28TS and the sidewall 28SW of the patterned mask layer 28P, the sidewall 26SW of the second electrode 26P, and a top surface of the capacitor dielectric material 24.

As shown in FIG. 4 and FIG. 5, a mask 80 may be formed on the spacer material 30, and an etching process 91 may be performed for removing the spacer material 30 without being covered by the mask 80 so as to form a patterned spacer material 30P on the patterned mask layer 28P, the second electrode 26P, and the capacitor dielectric material 24. The mask 80 may include a patterned photoresist material or other suitable mask materials, and the mask 80 may be removed after the etching process 91 and after the patterned spacer material 30P is formed, as shown in FIG. 5 and FIG. 6. As shown in FIG. 6 and FIG. 7, a first etching process (such as an etching process 92) using the patterned spacer material 30P as a mask may be performed to the capacitor dielectric material 24, and the capacitor dielectric material 24 may be etched to be the capacitor dielectric layer 24P by the etching process 92. As shown in FIG. 7 and FIG. 8, a second etching process (such as an etching process 93) may be performed after the etching process 92, the patterned spacer material 30P may be etched to be the spacer structure SP by the etching process 93, and the electrode material 22 may be etched to be the first electrode 22P by the etching process 93. The first electrode 22P and the spacer structure SP may be formed concurrently by the etching process 93, and the spacer structure SP may be formed on the sidewall 28SW of the patterned mask layer 28P and the sidewall 26SW of the second electrode 26P. In some embodiments, for controlling the formation of the spacer structure SP, a thickness of the patterned spacer material 30P (such as a thickness of the patterned spacer material 30P located above the patterned mask layer 28P in the vertical direction D1) may be less than the thickness of the patterned mask layer 28P, but not limited thereto. In addition, the etching process 92 and the etching process 93 may respectively include a dry etching process or other suitable etching approaches, and the process condition of the etching process 92 is different from that of the etching process 93. In the etching process 92, the etching rate of the capacitor dielectric material 24 is higher than that of the electrode material 22. In the etching process 93, the etching rate of the electrode material 22 and the etching rate of the patterned spacer material 30P are higher than the etching rate of the capacitor dielectric material 24. For example, a reactive process gas used in the etching process 92 may include boron trichloride (BCl₃) and chlorine (Cl₂), and a reactive process gas used in the etching process 93 may include chlorine (Cl₂) and methane (CH₄), but not limited thereto. It is worth noting that the method of forming the capacitor dielectric layer 24P, the spacer structure SP, and the first electrode 22 may include but is not limited to the steps shown in FIGS. 2-8 described above, and the capacitor dielectric layer 24P, the spacer structure SP, and the first electrode 22 illustrated in FIG. 8 and FIG. 1 may also be formed by other suitable approaches according to some design considerations.

As shown in FIG. 8 and FIG. 9, the cover layer 32 may be formed after the first electrode 22P and the spacer structure SP are formed, and the cover layer 32 may be formed conformally on the top surface 28TS of the patterned mask layer 28P, the spacer structure SP, the extending portion 24X of the capacitor dielectric layer 24P, the sidewall 22SW of the extending portion 22X of the first electrode 22P, and the top surface of the dielectric layer 12. In some embodiments, the thickness of the cover layer 32 (such as the thickness TK2) may be less than the thickness of the patterned mask layer 28P (such as the thickness TK1), the spacer structure SP may be disposed for increasing the overall thickness of the cover material located on the sidewall 28SW and the sidewall 26SW in the horizontal direction D2, the problem of peeling and/or breaking of the cover material due to the stress generated by the MIM capacitor stacked structure may be improved accordingly, and the related manufacturing yield may be enhanced. As shown in FIG. 9 and FIG. 1, after the step of forming the cover layer 32, the dielectric layer 40, the contact structure CT1, and the contact structure CT2 may be formed for forming the capacitor structure 101.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

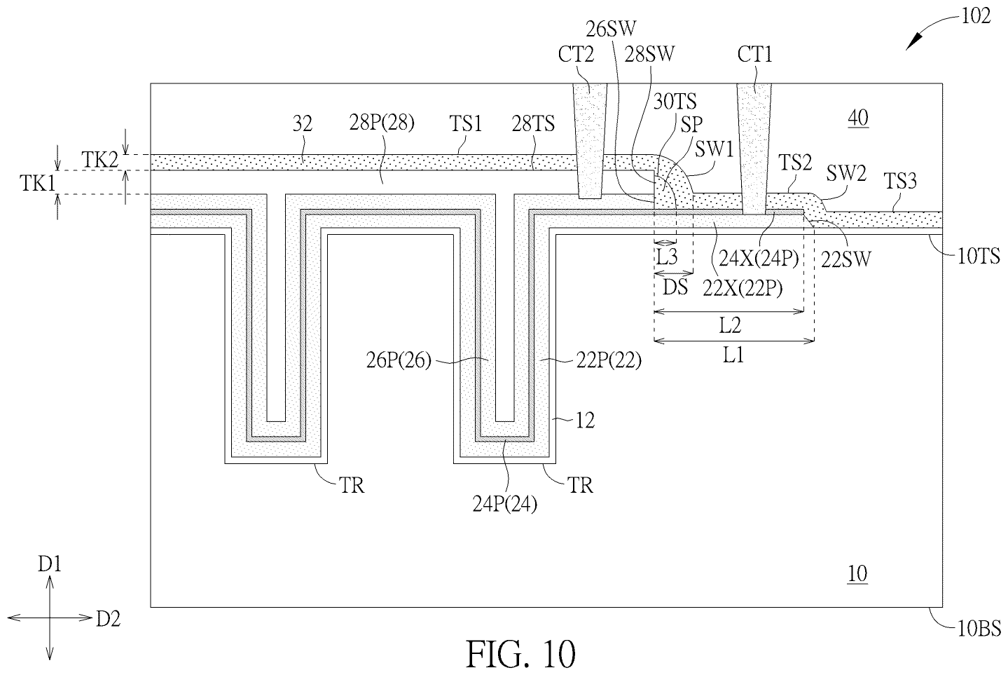

Please refer to FIG. 10. FIG. 10 is a schematic drawing illustrating a capacitor structure 102 according to a second embodiment of the present invention. As shown in FIG. 10, in the capacitor structure 102, the top surface 30TS of the spacer structure SP may be slightly lower than the top surface 28TS of the patterned mask layer 28P in the vertical direction D1 and higher than the top surface of the second electrode 26P in the vertical direction D1, and the cover layer 32 may directly contact the top surface 28TS and a part of the sidewall 28SW of the patterned mask layer 28P accordingly.

To summarize the above descriptions, according to the capacitor structure and the manufacturing method thereof in the present invention, the cover layer may be formed conformally on the patterned mask layer, the capacitor dielectric layer, and the first electrode, and the distance between the sidewall of the cover layer and the sidewall of the patterned mask layer may be relatively increased for increasing the thickness of the cover material located on the sidewall of the patterned mask layer and the sidewall of the second electrode in the horizontal direction. The problems of the cover material due to the stress generated by the capacitor stacked structure may be improved accordingly, and the related manufacturing yield may be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A capacitor structure, comprising:
a semiconductor substrate;
a first electrode disposed above the semiconductor substrate in a vertical direction;
a capacitor dielectric layer disposed on the first electrode;
a second electrode disposed on the capacitor dielectric layer, wherein the capacitor dielectric layer comprises a first extending portion, and the first extending portion is not covered by the second electrode in the vertical direction;
a patterned mask layer disposed on the second electrode; and
a cover layer disposed conformally on the patterned mask layer, the capacitor dielectric layer, and the first electrode, wherein the cover layer comprises a sidewall disposed above the first extending portion of the capacitor dielectric layer in the vertical direction, and a distance between the sidewall of the cover layer and a sidewall of the patterned mask layer in a horizontal direction is greater than a thickness of the cover layer disposed above the patterned mask layer in the vertical direction.

2. The capacitor structure according to claim 1, wherein the first electrode comprises a second extending portion located under the first extending portion in the vertical direction, the sidewall of the cover layer is located above the second extending portion in the vertical direction, and the cover layer is further conformally disposed on a sidewall of the second extending portion of the first electrode.

3. The capacitor structure according to claim 2, wherein the sidewall of the second extending portion of the first electrode is a sloping sidewall.

4. The capacitor structure according to claim 1, further comprising:
a spacer structure disposed on the sidewall of the patterned mask layer and a sidewall of the second electrode, wherein the spacer structure is located above the first extending portion of the capacitor dielectric layer in the vertical direction, and the cover layer is further conformally disposed on the spacer structure.

5. The capacitor structure according to claim 4, wherein a top surface of the spacer structure and a top surface of the patterned mask layer are coplanar or the top surface of the spacer structure is lower than the top surface of the patterned mask layer in the vertical direction.

6. The capacitor structure according to claim 4, wherein a length of the first extending portion of the capacitor dielectric layer in the horizontal direction is greater than a length of the spacer structure in the horizontal direction and the distance between the sidewall of the cover layer and the sidewall of the patterned mask layer in the horizontal direction.

7. The capacitor structure according to claim 4, wherein the spacer structure directly contacts the sidewall of the patterned mask layer, the sidewall of the second electrode, and the first extending portion of the capacitor dielectric layer, and the cover layer directly contacts a top surface of the patterned mask layer, the spacer structure, the first extending portion of the capacitor dielectric layer, and the first electrode.

8. The capacitor structure according to claim 4, wherein a material composition of the spacer structure is identical to a material composition of the cover layer.

9. The capacitor structure according to claim 4, wherein a material of the spacer structure and a material of the cover layer comprise silicon nitride, and a material of the patterned mask layer comprises oxide.

10. The capacitor structure according to claim 1, further comprising:
a trench disposed in the semiconductor substrate, wherein the first electrode, the capacitor dielectric layer, the second electrode, and the patterned mask layer are partially disposed in the trench.

11. A manufacturing method of a capacitor structure, comprising:
providing a semiconductor substrate;
forming a first electrode, a capacitor dielectric layer, a second electrode, and a patterned mask layer on the semiconductor substrate, wherein the first electrode is located above the semiconductor substrate in a vertical direction, the capacitor dielectric layer is located on the first electrode, the second electrode is located on the capacitor dielectric layer, the patterned mask layer is located on the second electrode, the capacitor dielectric layer comprises a first extending portion, and the first extending portion is not covered by the second electrode in the vertical direction; and
forming a cover layer conformally on the patterned mask layer, the capacitor dielectric layer, and the first electrode, wherein the cover layer comprises a sidewall located above the first extending portion of the capacitor dielectric layer in the vertical direction, and a distance between the sidewall of the cover layer and a sidewall of the patterned mask layer in a horizontal direction is greater than a thickness of the cover layer formed above the patterned mask layer in the vertical direction.

12. The manufacturing method of the capacitor structure according to claim 11, further comprising:
forming a spacer structure on the sidewall of the patterned mask layer and a sidewall of the second electrode before the cover layer is formed, wherein the spacer structure is located above the first extending portion of the capacitor dielectric layer in the vertical direction, and the cover layer is further conformally formed on the spacer structure.

13. The manufacturing method of the capacitor structure according to claim 12, wherein a top surface of the spacer structure and a top surface of the patterned mask layer are coplanar or the top surface of the spacer structure is lower than the top surface of the patterned mask layer in the vertical direction.

14. The manufacturing method of the capacitor structure according to claim 12, wherein a method of forming the capacitor dielectric layer, the spacer structure, and the first electrode comprises:
forming an electrode material on the semiconductor substrate;
forming a capacitor dielectric material on the electrode material, wherein the second electrode and the patterned mask layer are formed on the capacitor dielectric material;
forming a patterned spacer material on the patterned mask layer, the second electrode, and the capacitor dielectric material;
performing a first etching process using the patterned spacer material as a mask to the capacitor dielectric material, wherein the capacitor dielectric material is etched to be the capacitor dielectric layer by the first etching process; and
performing a second etching process after the first etching process, wherein the patterned spacer material is etched to be the spacer structure by the second etching process, and the electrode material is etched to be the first electrode by the second etching process.

15. The manufacturing method of the capacitor structure according to claim 14, wherein the first electrode and the spacer structure are formed concurrently by the second etching process.

16. The manufacturing method of the capacitor structure according to claim 14, wherein the first etching process comprises a dry etching process, and a reactive process gas used in the first etching process comprises boron trichloride (BCl₃) and chlorine (Cl₂).

17. The manufacturing method of the capacitor structure according to claim 14, wherein the second etching process comprises a dry etching process, and a reactive process gas used in the second etching process comprises chlorine (Cl₂) and methane (CH₄).

18. The manufacturing method of the capacitor structure according to claim 14, further comprising:
forming a trench in the semiconductor substrate before the electrode material is formed, wherein the first electrode, the capacitor dielectric layer, the second electrode, and the patterned mask layer are partially located in the trench, and the spacer structure is located outside the trench.

19. The manufacturing method of the capacitor structure according to claim 11, wherein the first electrode comprises a second extending portion located under the first extending portion in the vertical direction, the sidewall of the cover layer is located above the second extending portion in the vertical direction, and the cover layer is further conformally formed on a sidewall of the second extending portion.

20. The manufacturing method of the capacitor structure according to claim 11, wherein a length of the first extending portion of the capacitor dielectric layer in the horizontal direction is greater than the distance between the sidewall of the cover layer and the sidewall of the patterned mask layer in the horizontal direction.
